(19) United States
(12) Patent Application Publication
(10) Pub. No.: US 2025/0006676 A1
(43) Pub. Date: Jan. 2, 2025

(54) SEMICONDUCTOR PACKAGE AND METHOD OF MANUFACTURING THE SEMICONDUCTOR PACKAGE

(71) Applicant: SAMSUNG ELECTRONICS CO., LTD., SUWON-SI (KR)

(72) Inventor: Jinkyeong SEOL, Suwon-si (KR)

(21) Appl. No.: 18/641,504

(22) Filed: Apr. 22, 2024

(30) Foreign Application Priority Data
Jun. 30, 2023 (KR) 10-2023-0084835

(51) Int. Cl. H01L 23/00; H01L 23/31; H01L 23/48; H01L 25/065

(52) U.S. Cl. CPC H01L 24/06; H01L 23/3171; H01L 23/481; H01L 24/02; H01L 24/08; H01L 25/0657; H01L 2224/02373; H01L 2224/02375; H01L 2224/06177; H01L 2224/06515; H01L 2224/08145

(57) ABSTRACT

A semiconductor package includes a first semiconductor chip including first bonding pads disposed in a first main region on a first surface of a first substrate, first dummy bonding pads disposed in a first peripheral region on the first surface of the first substrate, and a first passivation layer disposed on the first surface, and a second semiconductor chip on the first semiconductor chip and including a wiring layer on a third surface of a second substrate and including redistribution pads in a second main region, second bonding pads disposed on the redistribution pads, second dummy bonding pads disposed in a second peripheral region on the wiring layer, and a second passivation layer disposed on the wiring layer. The first bonding pads and the second bonding pads are directly bonded to each other. The first dummy bonding pads and the second dummy bonding pads are directly bonded to each other.

### CROSS-REFERENCE TO RELATED APPLICATION

This application claims priority under 35 U.S.C. § 119 to Korean Patent Application No. 10-2023-0084835, filed on Jun. 30, 2023 in the Korean Intellectual Property Office, the disclosure of which is incorporated by reference in its entirety herein.

### 1. TECHNICAL FIELD

Example embodiments relate to a semiconductor package and a method of manufacturing the semiconductor package. More particularly, example embodiments relate to a semiconductor package including a plurality of sequentially stacked semiconductor chips and a method of manufacturing the same.

### 2. DISCUSSION OF RELATED ART

During the manufacture of a multi-chip package in which at least four semiconductor chips are stacked in a die to wafer bonding process, pad-to-pad direct bonding may be performed without using solder bumps. In this case, bonding pads arranged in a peripheral region are electrically connected to underlying redistribution pads and may receive electrical signals such as power signals or ground signals. However, when voids occur at the bonding interface in the peripheral region, leakage defects may occur due to the migration of copper ions based on a potential difference between the power signal and the ground signal between adjacent bonding pads.

### SUMMARY

Example embodiments provide a semiconductor package capable of preventing leakage defects due to voids at bonding interface and providing increased bonding quality.

Example embodiments provide a method of manufacturing the semiconductor package.

According to an embodiment of the present disclosure, a semiconductor package includes a first semiconductor chip including a first substrate including a first main region and a first peripheral region surrounding the first main region. A plurality of first bonding pads is disposed on a first surface of the first substrate in the first main region. A plurality of first dummy bonding pads is disposed on the first surface of the first substrate in the first peripheral region. A first passivation layer is disposed on the first surface of the first substrate. The plurality of first bonding pads and the plurality of first dummy bonding pads are disposed in the first passivation layer. The first passivation layer exposes a surface of each of the plurality of first bonding pads and the plurality of first dummy bonding pads. A second semiconductor chip is stacked on the first semiconductor chip. The second semiconductor chip includes a second substrate including a second main region and a second peripheral region surrounding the second main region. A wiring layer is on a third surface of the second substrate. An uppermost wiring of the wiring layer in the second main region comprises a plurality of redistribution pads. A plurality of second bonding pads is disposed on the plurality of redistribution pads. A plurality of second dummy bonding pads is disposed on the wiring layer in the second peripheral region. A second passivation layer is disposed on the wiring layer. The plurality of second bonding pads and the plurality of second dummy bonding pads are disposed in the second passivation layer. The second passivation layer exposes a surface of each of the plurality of second bonding pads and the plurality of second dummy bonding pads. The plurality of first bonding pads and the plurality of second bonding pads are directly bonded to each other. The plurality of first dummy bonding pads and the plurality of second dummy bonding pads are directly bonded to each other.

According to an embodiment of the present disclosure, a semiconductor package includes a buffer die. A plurality of intermediate core dies is sequentially stacked on the buffer die. A top core die is stacked on an uppermost intermediate core die of the plurality of intermediate core dies. Each of the plurality of intermediate core dies includes a substrate including a central region and a peripheral region surrounding the central region. The substrate has a first surface and a second surface opposite the first surface. A wiring layer is disposed on the first surface of the substrate. An uppermost wiring of the wiring layer in the central region comprises a plurality of redistribution pads. A plurality of first bonding pads is respectively disposed on the plurality of redistribution pads. A plurality of first dummy bonding pads is disposed on the wiring layer in the peripheral region. A first passivation layer is on the wiring layer. The plurality of first bonding pads and the plurality of first dummy bonding pads are disposed in the first passivation layer. The first passivation layer exposes a surface of each of the plurality of first bonding pads and the plurality of first dummy bonding pads. A plurality of second bonding pads is disposed on the second surface of the substrate in the central region. A plurality of second dummy bonding pads is disposed on the second surface of the substrate in the peripheral region. A second passivation layer is on the second surface of the substrate. The plurality of second bonding pads and the plurality of second dummy bonding pads are disposed in the second passivation layer. The second passivation layer exposes a surface of each of the plurality of second bonding pads and the plurality of second dummy bonding pads.

According to an embodiment of the present disclosure, a semiconductor package includes a buffer die. A plurality of intermediate core dies is sequentially stacked on the buffer die. A top core die is stacked on an uppermost intermediate core die of the plurality of intermediate core dies. A sealing member is on the buffer die and covers outer surfaces of the plurality of intermediate core dies and the top core die. Each of the plurality of intermediate core dies includes a substrate including a central region and a peripheral region surrounding the central region. The substrate has a first surface and a second surface opposite the first surface. A wiring layer is disposed on the first surface of the substrate. An uppermost wiring of the wiring layer in the central region comprises a plurality of redistribution pads. A plurality of first bonding pads is respectively disposed on the plurality of redistribution pads. A plurality of first dummy bonding pads is disposed on the wiring layer in the peripheral region. A first passivation layer is on the wiring layer. The first bonding pads and the first dummy bonding pads are disposed in the first passivation layer. The first passivation layer exposes a surface of each of the first bonding pads and the first dummy bonding pads. A plurality of second bonding pads is disposed on the second surface of the substrate in the central region. A plurality of second dummy bonding pads is disposed on the second surface of the substrate in the peripheral region. A second passivation layer is on the second surface of the substrate film. The second bonding pads and the second dummy bonding pads are disposed in the second passivation layer. The second passivation layer exposes a surface of each of the second bonding pads and the second dummy bonding pads. The first bonding pads directly contact the plurality of redistribution pads respectively.

Since redistribution pads are not provided in the peripheral region of the wiring layer, electrical signals such as a power signal or a ground signal may not be transmitted to the first dummy bonding pads. Even though a void occurs in the peripheral region between the core dies that are bonded to each other, a potential difference may not be generated between the adjacent first dummy bonding pads, so leakage defects due to migration of copper ions by the potential difference may be prevented. Accordingly, defects due to voids occurring at the bonding interface between the core dies may be prevented to increase bonding quality.

### BRIEF DESCRIPTION OF THE DRAWINGS

Example embodiments will be more clearly understood from the following detailed description taken in conjunction with the accompanying drawings. FIGS. 1 to 25 represent non-limiting, example embodiments as described herein.

FIG. 1 is a cross-sectional view illustrating a semiconductor package in accordance with an embodiment of the present disclosure.

FIG. 2 is an enlarged cross-sectional view illustrating portion ‘A’ in FIG. 1 in accordance with an embodiment of the present disclosure.

FIG. 3 is an enlarged cross-sectional view illustrating portion ‘B’ in FIG. 1 in accordance with an embodiment of the present disclosure.

FIG. 4 is a plan view illustrating a front surface of a first-stage intermediate core die of the semiconductor package of FIG. 1 in accordance with an embodiment of the present disclosure.

FIGS. 5 to 22 are views illustrating a method of manufacturing a semiconductor package in accordance with embodiments of the present disclosure.

FIG. 23 is a cross-sectional view illustrating a front surface of a second-stage intermediate core die of a semiconductor package in accordance with an embodiment of the present disclosure.

FIG. 24 is a cross-sectional view taken along the line M-M′ in FIG. 23 in accordance with an embodiment of the present disclosure.

FIG. 25 is a cross-sectional view illustrating a first-stage intermediate core die and a second-stage intermediate core bonded to each other of a semiconductor package in accordance with an embodiment of the present disclosure.

### DETAILED DESCRIPTION OF EMBODIMENTS

Hereinafter, example embodiments will be explained in detail with reference to the accompanying drawings.

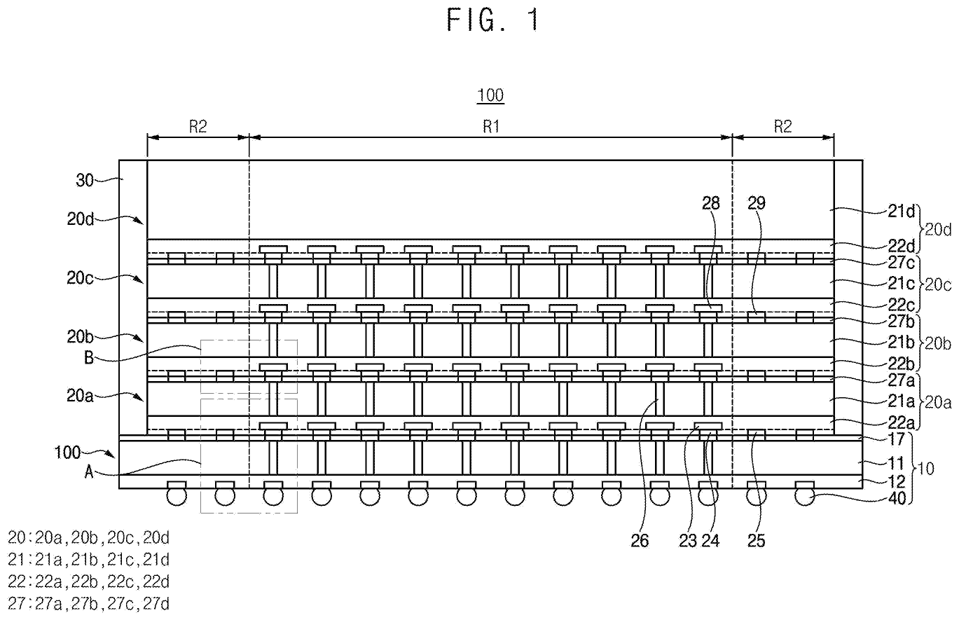

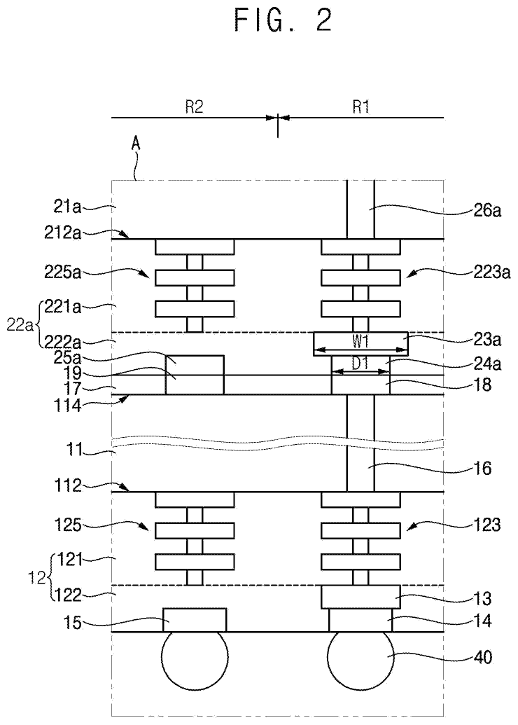

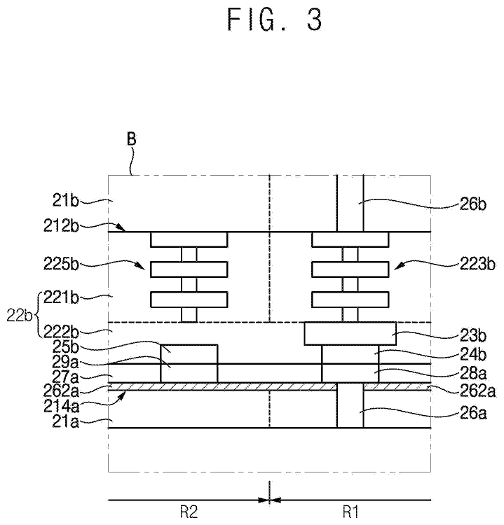

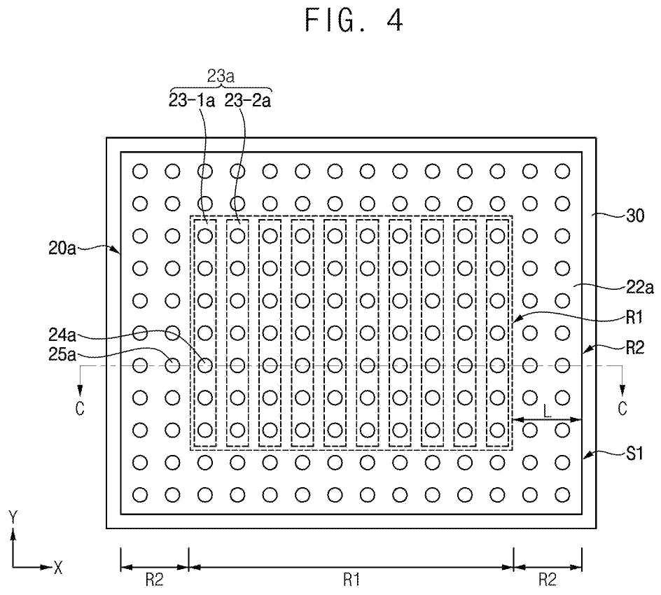

FIG. 1 is a cross-sectional view illustrating a semiconductor package in accordance with example embodiments. FIG. 2 is an enlarged cross-sectional view illustrating portion ‘A’ in FIG. 1. FIG. 3 is an enlarged cross-sectional view illustrating portion ‘B’ in FIG. 1. FIG. 4 is a plan view illustrating a front surface of a first-stage intermediate core die of the semiconductor package of FIG. 1.

Referring to FIGS. 1 to 4, a semiconductor package 100 may include semiconductor chips (e.g., dies) 20 stacked therein. The semiconductor package 100 may include a buffer die 10, and a plurality of intermediate core dies 20a, 20b, 20c and a top core die 20d sequentially stacked on the buffer die 10.

For example, in an embodiment, a plurality of semiconductor chips (e.g., dies) 20a, 20b, 20c and 20d may be stacked vertically. In an embodiment, the semiconductor chips (e.g., dies) 20a, 20b, 20d and 20d may be substantially the same as or similar to each other. Accordingly, same or like reference numerals will be used to refer to the same or like elements and repeated descriptions of the same elements may be omitted.

In an embodiment shown in FIG. 1, the semiconductor package as a multi-chip package is illustrated as including four stacked semiconductor chips 20a, 20b, 20c and 20d on the buffer die 10. However, embodiments of the present disclosure are not necessarily limited thereto. For example, in some embodiments the semiconductor package may include 8, 12, or 16 stacked semiconductor chips.

Each of the semiconductor chips 20a, 20b, 20c and 20d may include an integrated circuit chip completed by performing semiconductor manufacturing processes. In an embodiment, each semiconductor chip may include, for example, a memory chip or a logic chip. The semiconductor package 100 may include a memory device. The memory device may include a high bandwidth memory (HBM) device.

In example embodiments, the buffer die 10 and the plurality of semiconductor chips (e.g., dies) 20a, 20b, 20c and 20d may include a central region R1 and a peripheral region R2 surrounding the central region R1 (e.g., in a horizontal direction). The central region R1 may be a main region that includes through electrodes, through which electrical signals such as power signals and ground signals are transmitted. The peripheral region R2 may be a dummy region in which through electrodes are not disposed. However, embodiments of the present disclosure are not necessarily limited thereto. For example, in an embodiment through electrodes may be disposed in the peripheral region R2, and in this embodiment, electrical signals may not be transmitted to the through electrodes provided in the peripheral region R2. In an embodiment, a width L (FIG. 4) in one direction (e.g., the X direction) of the peripheral region R2, such as a length from an outer surface S1 of the semiconductor chip (e.g., die) may be within a range of about 20% to about 5% of a length of one side of the semiconductor chip (die). For example, in an embodiment the central region R1 may be spaced apart from the outer surface S1 of the semiconductor chip (die) by about 1.5 mm.

As illustrated in FIG. 2, the buffer die 10 may include a substrate 11, a front insulating layer 12, a plurality of first bonding pads 14, a plurality of first dummy bonding pads 15, a plurality of through electrodes 16, a backside insulating layer 17, a plurality of second bonding pads 18, and a plurality of second dummy bonding pads 19. Additionally, the buffer die 10 may further include conductive bumps 40 as conductive connection members respectively disposed on the first bonding pads 14 and the first dummy bonding pads 15. The buffer die 10 may be mounted on a package substrate or an interposer via the conductive bumps 40. For example, in an embodiment the conductive bump 40 may include a solder bump. Alternatively, the conductive bump 40 may include a pillar bump and a solder bump formed on the pillar bump.

The substrate 11 may have a first surface 112 and a second surface 114 opposite to the first surface 112 (e.g., opposite in the vertical direction). In an embodiment, the first surface 112 may be an active surface, and the second surface 114 may be a non-active surface. Circuit patterns may be disposed on the first surface 112 of the substrate 11. The first surface 112 may be referred to as a front surface on which the circuit patterns are formed, and the second surface may be referred to as a backside surface.

For example, in an embodiment the substrate 11 may be a single crystal silicon substrate. The circuit patterns may include transistors, capacitors, diodes, etc. The circuit patterns may constitute circuit elements. Accordingly, the buffer die 10 may be a semiconductor device having a plurality of circuit elements formed therein.

As illustrated in FIG. 2, the front insulating layer 12 as an insulation interlayer may be formed on the first surface 112 of the substrate 11, such as the front surface. In an embodiment, the front insulating layer 12 may include a wiring layer 121 and a first passivation layer 122 sequentially disposed on the first surface 112 of the substrate 11. Additionally, the first bonding pad 14 and the first dummy bonding pads 15 may be arranged in an outermost insulating layer of the front insulating layer 12.

For example, the wiring layer 121 may include a plurality of insulating layers, wirings 123 and 125 in the insulating layers, and redistribution pads 13 as uppermost wirings. In an embodiment, the insulating layers may be formed to include oxides such as silicon oxide, carbon-doped oxide, fluorine-doped oxide, etc.

The wiring layer 121 may include a plurality of wirings 123 in the central region R1 and a plurality of wirings 125 in the peripheral region R2. For example, in an embodiment the wiring layer 121 may include a metal wiring structure including the plurality of wirings 123, 125 vertically stacked in buffer layers and insulating layers. For example, in an embodiment the wirings may include aluminum (Al), copper (Cu), tin (Sn), nickel (Ni), gold (Au), platinum (Pt), or alloys thereof.

In an embodiment, the wiring layer 121 may include a plurality of redistribution pads 13 disposed in the central region R1. For example, as shown in FIG. 2 the redistribution pads 13 may be the uppermost wirings among the plurality of wirings 123 disposed in the central region R1. Each of the redistribution pads 13 may include a redistribution line extending in a first direction (Y direction).

The plurality of first bonding pads 14 may be disposed in the first passivation layer 122 in the central region R1 and the plurality of first dummy bonding pads 15 may be disposed in the first passivation layer 122 in the peripheral region R2. In an embodiment, the first bonding pads 14 and the first dummy bonding pads 15 may be exposed from an outer surface (e.g., a bottommost surface in the vertical direction) of the first passivation layer 122. The first bonding pads 14 may be respectively disposed on the redistribution pads 13. In an embodiment, the first bonding pads 14 may directly contact the redistribution pads 13.

In an embodiment, the first passivation layer 122 may include a first protective layer and a second protective layer stacked on the first protective layer. However, embodiments of the present disclosure are not necessarily limited thereto. For example, in an embodiment the first passivation layer may further include a third protective layer stacked on the second protective layer. In an embodiment, the first passivation layer may include silicon oxide, silicon nitride, or silicon carbonitride.

In an embodiment, an insulation interlayer may be disposed on the first surface 112 of the substrate 11 to cover the circuit patterns. In an embodiment, the insulation interlayer may be formed to include, for example, silicon oxide or a low dielectric material. The insulation interlayer may include lower wiring therein, which are electrically connected to the circuit patterns. Accordingly, the circuit pattern may be electrically connected to the first bonding pad 14 by the lower wirings and the wirings.

The through electrode 16 (e.g., a through silicon via TSV) may vertically penetrate the insulation interlayer and extend from the first surface 112 to the second surface 114 of the substrate 11. In an embodiment, the through electrode 16 may directly contact a lowermost wiring of the metal wiring structure. Accordingly, the through electrode 16 may be electrically connected to the first bonding pad 14 by the wirings 123 and the redistribution pad 14.

The backside insulating layer 17 as a second passivation layer may be formed on (e.g., formed directly thereon) the second surface 114 of the substrate 11, such as the backside surface. In an embodiment, the plurality of second bonding pads 18 may be disposed in the backside insulating layer 17 in the central region R1 and the plurality of second dummy bonding pads 19 may be disposed in the backside insulating layer 17 in the peripheral region R2. The second bonding pads 18 and the second dummy bonding pads 19 may be exposed from an outer surface (e.g., an uppermost surface in the vertical direction) of the backside insulating layer 17. The second bonding pad 18 may be electrically connected to the through electrode 16, and the second dummy bonding pad 19 may not be electrically connected to the through electrode. For example, the second bonding pad 18 may be disposed on (e.g., disposed directly thereon) an exposed surface of the through electrode 16. In an embodiment, the backside insulating layer 17 may include silicon oxide, carbon-doped silicon oxide, silicon carbonitride (SiCN), etc. Accordingly, the first and second bonding pads 14 and 18 may be electrically connected to each other by the through electrode 16 whereas the first and second dummy bonding pads 15, 19 are not electrically connected to each other.

In example embodiments, each of the intermediate core dies 20 may include a substrate 21 and a front insulating layer 22 disposed on a front surface of the substrate 21. First bonding pads 24 and first dummy bonding pads 25 are disposed in the front insulating layer 22. A backside insulating layer 27 is disposed on a backside surface of the substrate 21. The second bonding pads 28 and second dummy bonding pads 29 are disposed in the backside insulating layer 27. In addition, each of the intermediate core dies 20 may further include a through electrode 26 that penetrates the substrate 21 and is electrically connected to the first and second bonding pads 24 and 28.

In an embodiment, an intermediate core die stack may be bonded onto the buffer die 10. In an embodiment, the intermediate core die stack may include the intermediate core dies 20a, 20b, 20c stacked in three stages (e.g., three intermediate core dies stacked on each other in the vertical direction). In this embodiment, the intermediate core die stack may include, but is not necessarily limited to, intermediate core dies 20a, 20b and 20c stacked in the three stages. However, in some embodiments the intermediate core die stack may include intermediate core dies stacked in 7, 11, 15 stages, etc.

As illustrated in FIGS. 2 and 3, in an embodiment the first-stage intermediate core die 20a of the intermediate core die stack may include a substrate 21a, a front insulating layer 22a, a plurality of redistribution pads 23a, a plurality of first bonding pads 24a, a plurality of first dummy bonding pads 25a, a plurality of through electrodes 26a, a backside insulating layer 27a, a plurality of second bonding pads 28a and a plurality of second dummy bonding pads 29a.

The substrate 21a may have a first surface 212a and a second surface 214a opposite to the first surface 212a (e.g., in the vertical direction). In an embodiment, the first surface 212a may be an active surface, and the second surface 214a may be a non-active side. Circuit patterns may be disposed on the first surface 212a of the substrate 21a. The front insulating layer 22a which is as an insulation interlayer may be formed on the first surface 212a of the substrate 21a, such as a front surface. The front insulating layer 22a may include a wiring layer 221a and a first passivation layer 222a. In an embodiment, the backside insulating layer 17 and the first passivation layer 222a may be directly bonded to each other.

The wiring layer 221a may include a plurality of wirings 223a in the central region R1 and a plurality of wirings 225a in the peripheral region R2. For example, the metal wiring layer 221a may include a metal wiring structure including the plurality of wirings 223a, 225a vertically stacked in buffer layers and insulating layers. For example, in an embodiment the wirings may include aluminum (Al), copper (Cu), tin (Sn), nickel (Ni), gold (Au), platinum (Pt), or alloys thereof. However, embodiments of the present disclosure are not necessarily limited thereto.

The wiring layer 221a may include a plurality of redistribution pads 23a disposed in the central region R1. As shown in FIG. 2, the redistribution pads 23a may be uppermost wirings among the plurality of wirings 223a disposed in the central region R1.

As illustrated in FIG. 4, each of the redistribution pads 23a may include a redistribution line that extends in a first direction (e.g., the Y direction). The redistribution pads 23a may include power redistribution lines 23-la and ground redistribution lines 23-2a that extend in the first direction (e.g., the Y direction) respectively. In an embodiment, the power redistribution line 23-la may be electrically connected to the wirings 223a in the central region R1 to supply power signals to the plurality of through electrodes 26a that are arranged along the first direction (e.g., the Y direction). In an embodiment, the ground redistribution line 23-2a may be electrically connected to the wirings 223a in the central region R1 to supply ground signals to the plurality of through electrodes 26a that are arranged along the first direction (e.g., the Y direction).

The redistribution lines may be spaced apart from each other along a second direction (e.g., the X direction) perpendicular to the first direction (e.g., the Y direction). As shown in FIG. 4, in an embodiment he power redistribution lines 23-la and the ground redistribution lines 23-2a may be alternately arranged along the second direction (X direction). However, embodiments of the present disclosure are not necessarily limited thereto. For example, in some embodiments one or more ground redistribution lines 23-2a may be arranged between two adjacent power redistribution lines 23-la, or one or more power redistribution lines 23-la may be arranged between two adjacent ground redistribution lines 23-2a.

In an embodiment, the redistribution pads 23a may be arranged in the central region R1 and may be electrically connected to the through electrodes 26a through the wirings 223a of the wiring layer 221a in the central region R1. The redistribution pads 23a may not be disposed in the peripheral region R2.

The plurality of first bonding pads 24a may be disposed in the first passivation layer 222a in the central region R1 and the plurality of first dummy bonding pads 25a may be disposed in the first passivation layer 222a in the peripheral region R2. The first bonding pads 24a and the first dummy bonding pads 25a may be exposed from an outer surface (e.g., a bottommost surface in the vertical direction) of the first passivation layer 222a. The first bonding pads 24a may be respectively disposed on the redistribution pads 23a. The first bonding pads 24a may directly contact the redistribution pads 23a.

In an embodiment, the first passivation layer 222a may include a first protective layer and a second protective layer stacked on the first protective layer. However, embodiments of the present disclosure are not necessarily limited thereto. For example, in an embodiment the first passivation layer may further include a third protective layer stacked on the second protective layer. The first passivation layer may include silicon oxide, silicon nitride, or silicon carbonitride.

In an embodiment, an insulation interlayer may be disposed on the first surface 212a of the substrate 21a to cover the circuit patterns. In an embodiment, the insulation interlayer may be formed to include, for example, silicon oxide or a low dielectric material. The lower wiring which are electrically connected to the circuit patterns may be disposed in the insulation interlayer. Accordingly, the circuit pattern may be electrically connected to the first bonding pad 24a by the lower wirings and the wirings.

For example, in an embodiment the first bonding pads 24a and the first dummy bonding pads 25a may include copper (Cu), aluminum (Al), tungsten (W), nickel (Ni), molybdenum (Mo), gold (Au), silver (Ag), chromium (Cr), tin (Sn), titanium (Ti), or an alloy thereof. In this embodiment, the redistribution pad 23a may include aluminum (Al), and the first bonding pad 24a and the first dummy bonding pad 25a may include copper (Cu). In an embodiment, the redistribution pad 23a may have a first width W1 (e.g., length in a horizontal direction parallel to an upper surface of the substrate 11). The first bonding pad 24a and the first dummy bonding pad 25a may have a first diameter D1 (e.g., length in a horizontal direction parallel to an upper surface of the substrate 11) less than the first width W1. For example, in an embodiment the first width W1 of the redistribution pad 23a may be within a range of about 5 μm to about 30 μm, and the first diameters D1 of the first bonding pad 24a and the first dummy bonding pad 25a may be in a range of about 2 μm to about 15 μm.

The through electrode 26a may vertically extend from the first surface 212a to the second surface 214a of the substrate 21a. The through electrode 26a may be electrically connected to the first bonding pad 24a by the wirings 223a and the redistribution pad 23a.

The backside insulating layer 27a as a second passivation layer may be formed on the second surface 214a of the substrate 21a, such as a backside surface. The plurality of second bonding pads 28a may be disposed in the backside insulating layer 27a in the central region R1 and the plurality of second dummy bonding pads 29a may be disposed in the backside insulating layer 27a in the peripheral region R2. The second bonding pads 28a and the second dummy bonding pads 29a may be exposed from an outer surface (e.g., an uppermost surface in the vertical direction) of the backside insulating layer 27a. The second bonding pad 28a may be electrically connected to the through electrode 26a, and the second dummy bonding pad 29a may not be electrically connected to the through electrode. For example, the second bonding pad 28a may be disposed on (e.g., disposed directly thereon) an exposed surface of the through electrode 26a. In an embodiment, the backside insulating layer 27a may include silicon oxide, carbon-doped silicon oxide, silicon carbonitride (SiCN), etc. Accordingly, the first and second bonding pads 24a and 28a may be electrically connected to each other by the through electrode 26a.

The second bonding pad 28a may be disposed in the backside insulating layer 27a. Accordingly, the first and second bonding pads 23a and 28a may be electrically connected to each other by the through electrode 26a.

Similarly, in an embodiment the second-stage intermediate core die 20b of the intermediate core die stack DS1 may include a substrate 21b, a front insulating layer 22b, a plurality of redistribution pads 23b, a plurality of first bonding pads 24b, a plurality of first dummy bonding pads 25b, a plurality of through electrodes 25b, a backside insulating layer 27b, a plurality of second bonding pads 28b, and a plurality of second dummy bonding pads 29b. Since the core dies 20a, 20b, 20c and 20d are substantially the same as or similar to each other, same or like reference numerals will be used to refer to the same or like elements and repeated descriptions of the same elements may be omitted for economy of description.

As illustrated in FIG. 2, in an embodiment the first-stage intermediate core die 20a and the buffer die 10 may be bonded to each other by hybrid bonding. For example, in an embodiment the second bonding pad 18 of the buffer die 10 and the first bonding pad 24a of the intermediate core die 20a may be bonded to each other by copper-copper hybrid bonding (Cu-Cu Hybrid Bonding). The front surface of the intermediate core die 20a, such as the front side insulating layer 23a on the first surface 212a of the substrate 21a may be directly bonded to the backside insulating layer 17 of the substrate 11 of the buffer die 10.

As illustrated in FIG. 3, in an embodiment the second-stage intermediate core die 20b and the first-stage intermediate core die 20a may be bonded to each other by hybrid bonding. For example, in an embodiment the second bonding pad 28a of the first-stage intermediate core die 20a and the first bonding pad 24b of the second-stage intermediate core die 20b may be bonded to each other by copper-copper hybrid bonding (e.g., Cu—Cu Hybrid Bonding). Additionally, the second dummy bonding pad 29a of the first intermediate core die 20a and the first dummy bonding pads 25b of the second intermediate core die 20b may directly contact each other.

The front insulating layer 22b on the front surface of the second-stage intermediate core die 20b may be directly bonded to the backside insulating layer 27a on the backside surface of the first-stage intermediate core die 20a. The outermost insulating layers (e.g., the first and second passivation layers) of the backside insulating layer 27a and the front insulating layer 22b may include an insulating material that directly contacts each other and provides excellent bonding strength, thereby providing a bonding structure. In an embodiment, the backside insulating layer 27a and the front insulating layer 22b may be bonded to each other by a high temperature annealing process while in direct contact with each other. Here, the bonding structure may have a relatively stronger bonding strength by covalent bonding.

Similarly, the third-stage intermediate core die 20c and the second-stage intermediate core die 20b may be bonded to each other by hybrid bonding. For example, in an embodiment the second bonding pad 28b of the second-stage intermediate core die 20b and a first bonding pad 24c of the third-stage intermediate core die 20c may be bonded to each other by copper-copper hybrid bonding (e.g., Cu—Cu Hybrid Bonding). A front insulating layer 22c on the front surface of the third-stage intermediate core die 20c may be directly bonded to the backside insulating layer 27b on the backside surface of the second-stage intermediate core die 20b.

In example embodiments, the top core die 20d may be bonded onto the intermediate core die stack. In an embodiment, a thickness (e.g., length in the vertical direction) of the top core die 20d may be greater than thicknesses (e.g., lengths in the vertical direction) of the intermediate core dies 20a, 20b, 20c. In an embodiment, the thickness of the top core die 20d may be in a range of about 100 μm to about 300 μm. The thicknesses of the intermediate core dies 20a, 20b, 20c may be in a range of about 20 μm to about 50 μm.

In an embodiment, the top core die 20d of the top core die stack DS2 and the intermediate core die 20c of the intermediate core die stack may be bonded to each other by hybrid bonding. The front insulating layer 22d on a front surface of the top core die 20d may be directly bonded to a backside insulating layer 27c on a backside surface of the intermediate core die 20c, and a second bonding pad 28c of the intermediate core die 20c and a first bonding pads 24d of the top core die 20d may be bonded to each other by copper-copper hybrid bonding. A second dummy bonding pad 29c of the third-stage middle core die 20c and a first dummy bonding pads 25d of the top core die 20d may directly contact each other. A front insulating layer 22d on a front surface of the top core die 20d may be directly bonded to a backside insulating layer 27c on a backside surface of the third-stage intermediate core die 20c.

In example embodiments, a gap filling portion 30 may be arranged to cover outer surfaces (e.g., lateral ends) of the intermediate core dies 20a, 20b and 20c and the top core die sequentially stacked on the buffer die 10. For example, in an embodiment the gap filling portion 30 may be formed by a conformal deposition process such as an atomic layer deposition (ALD) process or a chemical vapor deposition (CVD) process. However, embodiments of the present disclosure are not necessarily limited thereto. The gap filling portion may include an inorganic dielectric layer or an organic dielectric layer. In an embodiment, the inorganic dielectric layer may include silicon oxide, silicon oxynitride, phosphosilicate glass (PSG), boro-phosphosilicate glass (BPSG), etc. The organic dielectric layer may include a polymer or the like.

In example embodiments, a width of the buffer die 10 may be the same as a width of intermediate core die stack. The width of the intermediate core die stack may be the same as a width of the top core die 20d. An outer surface of the buffer die 10 may be coplanar with an outer surface of the gap filling portion 30. Thus, the outer surface of the buffer die 10 and the outer surface of the gap filling portion 30 may be aligned with each other.

As mentioned above, in an embodiment the semiconductor package 100 may include the intermediate core dies 20a, 20b, 20c and the top core die 20d sequentially stacked on the buffer die 10 (e.g., in the vertical direction). Each of the intermediate core dies 20a, 20b, 20c and the top core die 20d may include the front insulating layer 22 disposed on the first surface 221 of the substrate 21 that includes the central region R1 and the peripheral region R2 around the central region R1. The front insulating layer 22 may include the wiring layer 221 having the redistribution pads 23 as the uppermost wirings in the central region R1, the first bonding pads 24 respectively disposed on the redistribution pads 23, the first dummy bonding pads 25 provided on the wiring layer 221 in the peripheral region R2, and the first passivation layer 222 on the wiring layer 221 to expose the first bonding pads 24 and the first dummy bonding pads 25.

Since redistribution pads are not disposed in the peripheral region R2 of the wiring layer 221, a power signal or a ground signal may not be transmitted to the first dummy bonding pads 25. Even though a void occurs in the peripheral region R2 between the core dies 20a, 20b, 20c, 20d that are bonded to each other, a potential difference may not be generated between adjacent first dummy bonding pads 25, so leakage defects due to migration of copper ions by the potential difference may be prevented. Accordingly, defects due to voids occurring at the bonding interface between the core dies may be prevented to increase bonding quality.

Hereinafter, a method of manufacturing the semiconductor package of FIG. 1 will be described. A case where the semiconductor package includes a high bandwidth memory (HBM) device will be described. However, it will be understood that a method of manufacturing a semiconductor package in accordance with example embodiments is not limited thereto.

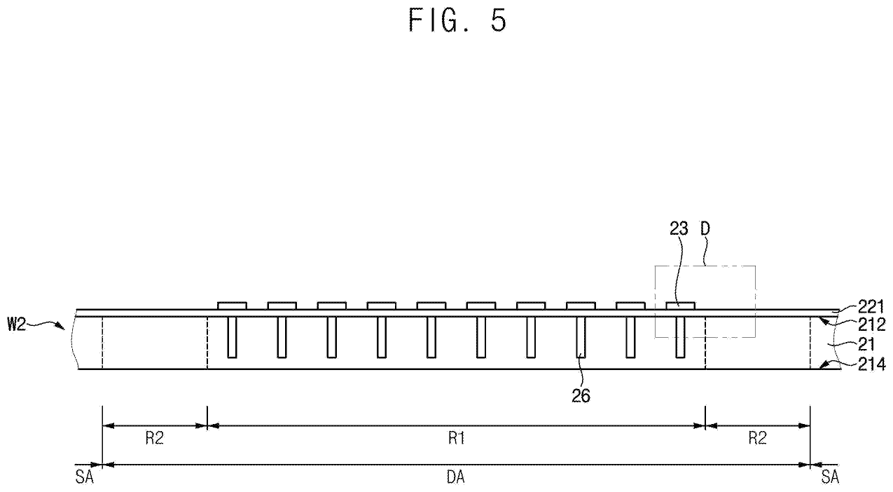

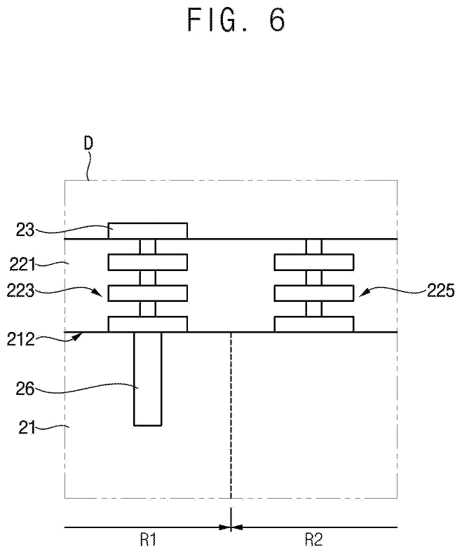

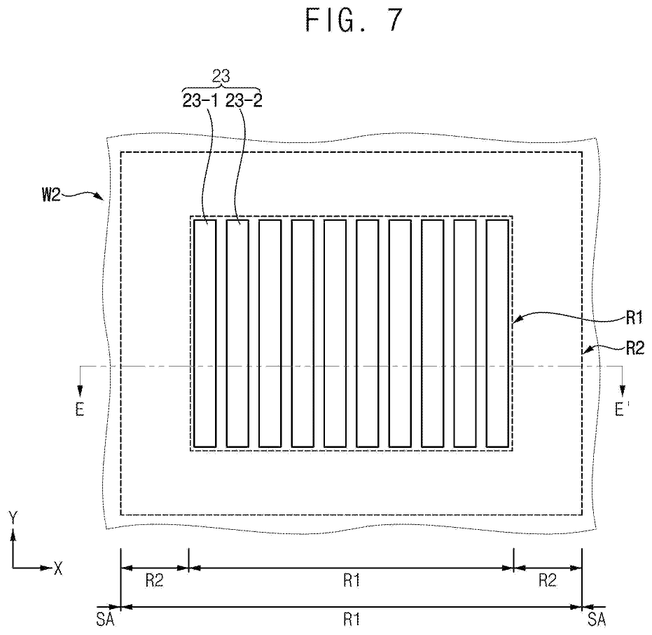

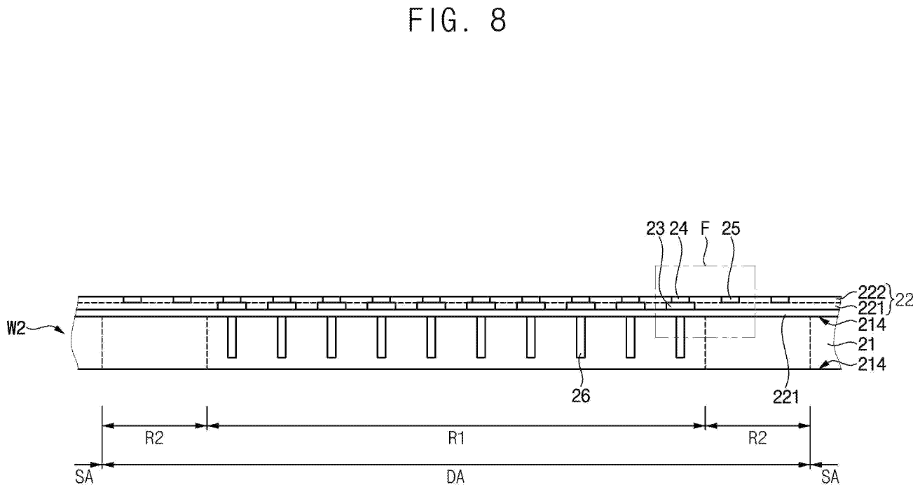

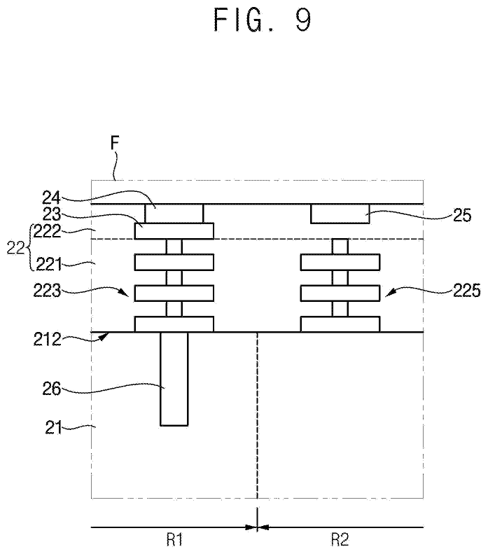

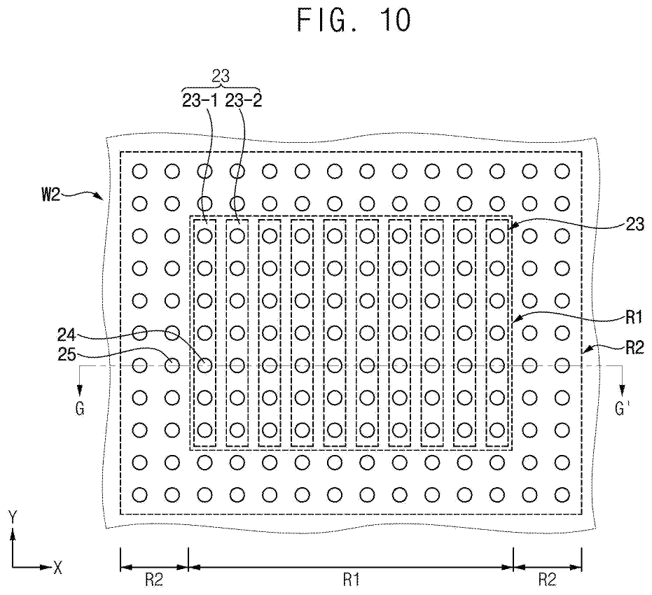

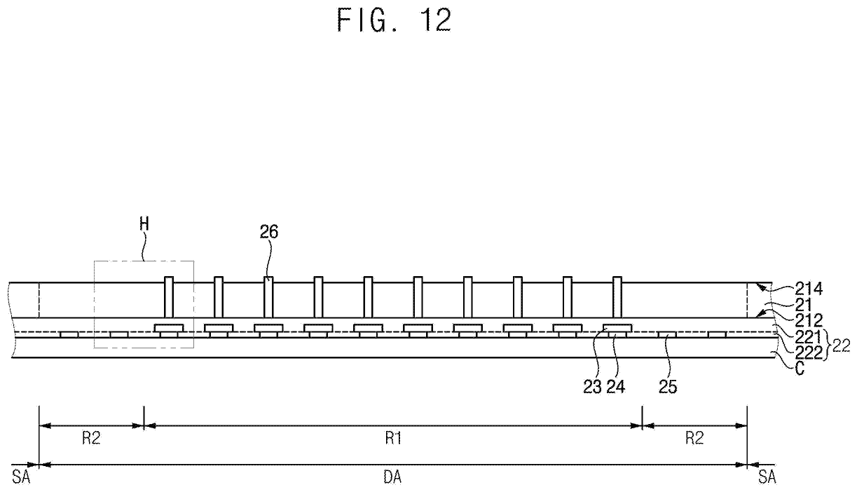

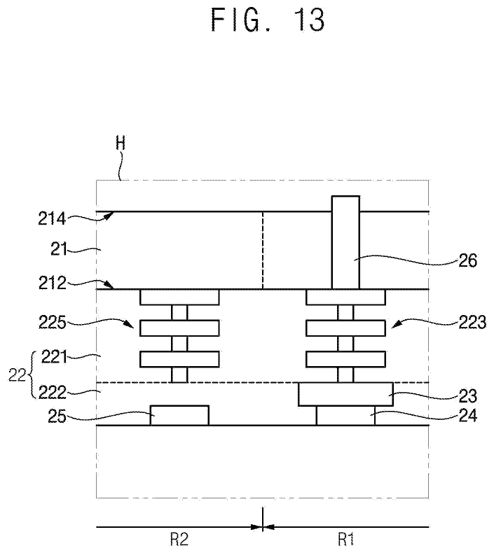

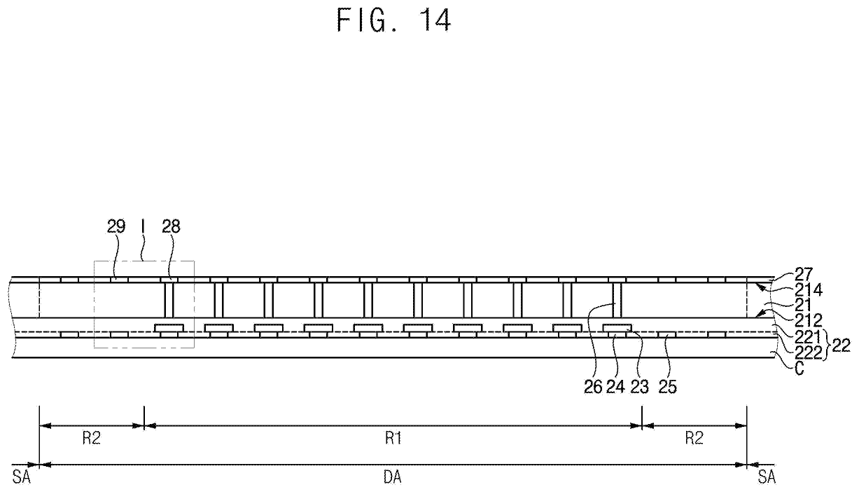

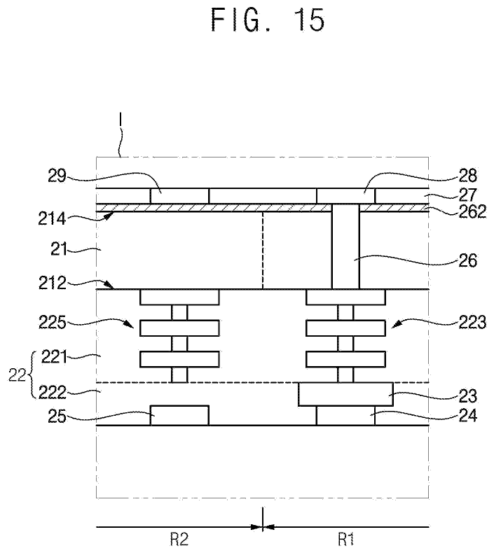

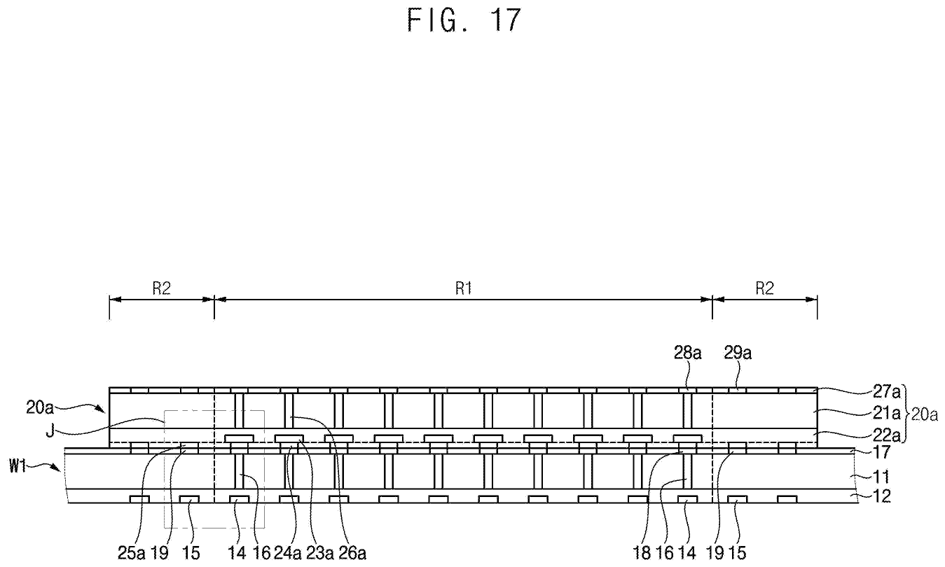

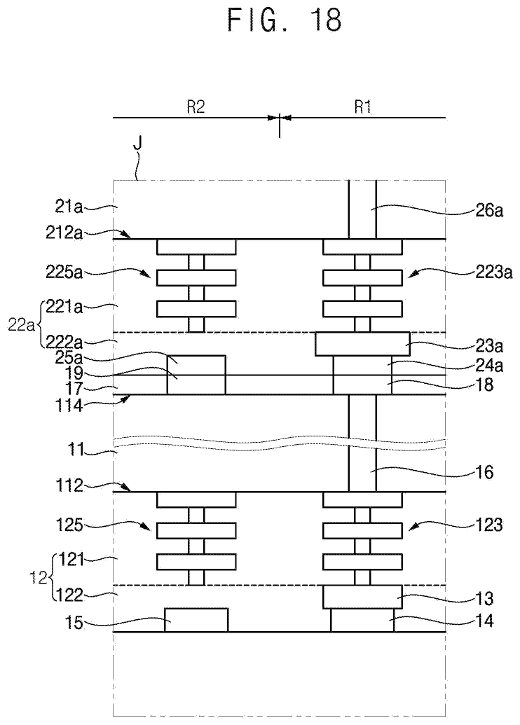

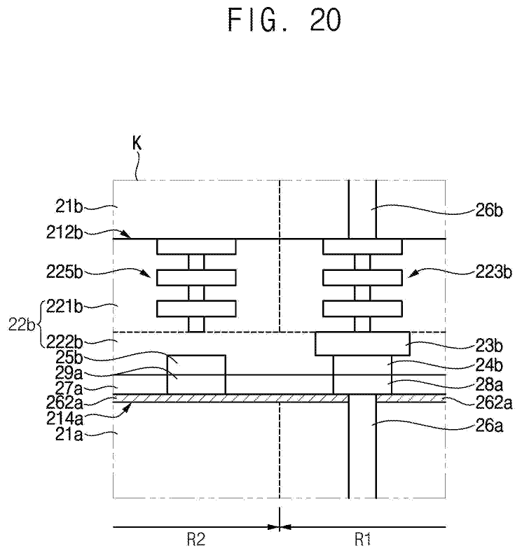

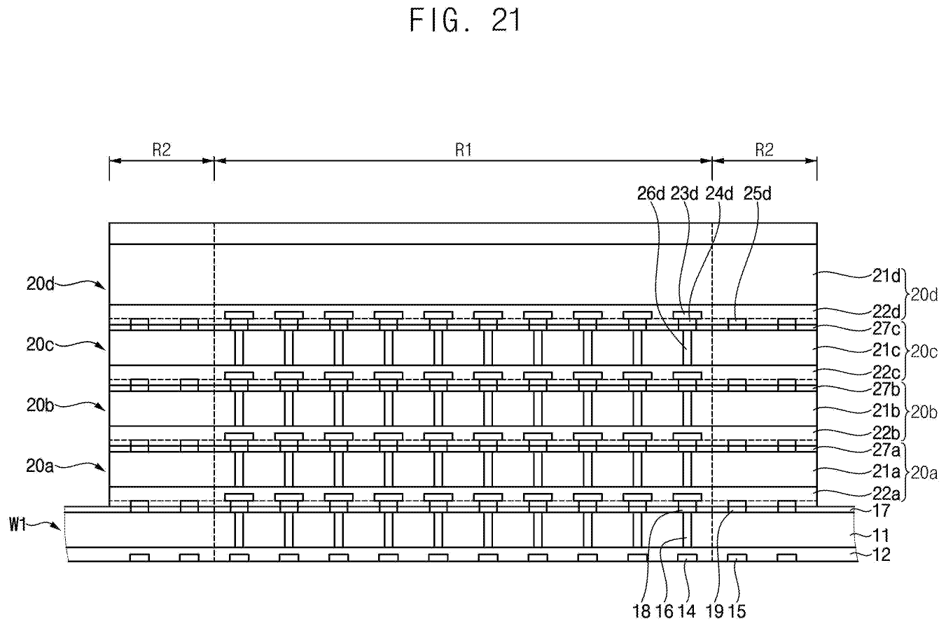

FIGS. 5 to 22 are views illustrating a method of manufacturing a semiconductor package in accordance with example embodiments. FIGS. 5, 8, 11, 12, 14, 16, 17, 19, 21, and 22 are cross-sectional views illustrating a method of manufacturing a semiconductor package in accordance with example embodiments. FIG. 6 is an enlarged cross-sectional view illustrating portion ‘D’ in FIG. 5. FIG. 7 is a plan view of FIG. 5. FIG. 5 is a cross-sectional view taken along the line E-E′ in FIG. 7. FIG. 9 is an enlarged cross-sectional view illustrating portion ‘F’ in FIG. 8. FIG. 10 is a plan view of FIG. 8. FIG. 8 is a cross-sectional view taken along the line G-G′ in FIG. 10. FIG. 13 is an enlarged cross-sectional view illustrating portion ‘H’ in FIG. 12. FIG. 15 is an enlarged cross-sectional view illustrating portion ‘I’ in FIG. 14. FIG. 18 is an enlarged cross-sectional view illustrating portion ‘J’ in FIG. 17. FIG. 20 is an enlarged cross-sectional view illustrating portion ‘K’ in FIG. 20.

Referring to FIGS. 5 to 16, first, a second wafer W2 may be individualized into semiconductor chips (e.g., core dies) 20.

As illustrated in FIGS. 5 to 7, the second wafer W2 including a plurality of semiconductor chips (e.g., core dies) formed therein may be prepared.

In example embodiments, the second wafer W2 may include a substrate 21 having a first surface 212 and a second surface 214 opposite the first surface 212 (e.g., in the vertical direction). Additionally, the second wafer W2 may include a plurality of through electrodes 26 that are provided in the substrate 21

In an embodiment, the substrate 21 may include a die region DA where circuit patterns and cells are formed and a scribe lane region SA surrounding the die region DA. The substrate 21 may be cut along the scribe lane region SA that divides the plurality of die regions DA of the second wafer W2 by a following dicing process to form individualized semiconductor chips. The substrate 21 may include a central region R1 and a peripheral region R2 surrounding the central region R1. The central region R1 and the peripheral region R2 may both be disposed in the die region DA. The central region R1 may be a main region including through electrodes that are provided to transmit electrical signals such as power signals and ground signals therethrough. The peripheral region R2 may be a dummy region in which through electrodes are not provided.

For example, in an embodiment the substrate 21 may include silicon, germanium, silicon-germanium, or III-V compounds, e.g., GaP, GaAs, GaSb, etc. In some embodiments, the second substrate 21 may be a silicon-on-insulator (SOI) substrate, or a germanium-on-insulator (GOI) substrate.

The circuit patterns may include transistors, capacitors, diodes, etc. The circuit patterns may constitute circuit elements. Accordingly, the semiconductor chip may be a semiconductor device with a plurality of the circuit elements formed therein. In an embodiment, the circuit patterns may be formed on the first surface 212 of the substrate 21 by performing a FEOL (Front End of Line) process for manufacturing semiconductor devices. The surface of the substrate on which the FEOL process is performed may be referred to as a front surface of the substrate, and a surface opposite to the front surface may be referred to as a backside surface.

The circuit element may include a plurality of memory devices. Examples of the memory devices include a volatile semiconductor memory device and a non-volatile semiconductor memory device. Examples of the volatile semiconductor memory device may be DRAM, SRAM, etc. Examples of the non-volatile semiconductor memory devices may be EPROM, EEPROM, Flash EEPROM, etc.

In example embodiments, the second wafer W2 may include a wiring layer 221 provided on the first surface 212 of the substrate 21, such as the front surface. In an embodiment, the wiring layer 221 may be formed by performing a wiring process called back-end-of-line (BEOL).

As illustrated in FIG. 6, the wiring layer 221 may include a plurality of insulating layers, wirings 223 and 225 disposed in the insulating layers, and redistribution pads 23 as uppermost wirings (e.g., in the vertical direction). In an embodiment, the insulating layers may be formed to include oxides such as silicon oxide, carbon-doped oxide, fluorine-doped oxide, etc.

The wiring layer 221 may include a plurality of wirings 223 in the central region R1 and a plurality of wirings 225 in the peripheral region R2. For example, the wiring layer 221 may include a metal wiring structure including the plurality of wirings 223, 225 vertically stacked in buffer layers and insulating layers. For example, in an embodiment the wirings may include aluminum (Al), copper (Cu), tin (Sn), nickel (Ni), gold (Au), platinum (Pt), or alloys thereof.

For example, in an embodiment the wirings 223 and 225 of the wiring layer 221 may include a first metal wiring, a second metal wiring and a third metal wiring vertically stacked on one another, and the first to third metal wirings may be electrically connected to each other by vias that are interposed therebetween. The lowermost first metal wiring may be electrically connected to an impurity region of the substrate 21 or the circuit pattern by an underlying contact plug. The uppermost third metal wiring may be electrically connected to the redistribution pad 23 through the via. In FIG. 6, metal wiring of three layers are illustrated. However, embodiments of the present inventive concept are not necessarily limited thereto. For example, the wirings may include various numbers of metal wires, such as metal wires of five layers and vias interposed therebetween.

As illustrated in FIG. 7, the wiring layer 212 may include a plurality of the redistribution pads 23 provided in the central region R1. In an embodiment, the redistribution pads 23 may be the uppermost wirings among the plurality of wirings 223 provided in the central region R1. Each of the redistribution pads 23 may include a redistribution line extending in a first direction (e.g., the Y direction). Each of the redistribution pads 23 may include a redistribution line that extends in the first direction (e.g., the Y direction). The redistribution pads 23 may include power redistribution lines 23-1 and ground redistribution lines 23-2 that extend in the first direction (e.g., the Y direction) respectively. In an embodiment, the power redistribution line 23-1 may be electrically connected to the wirings 223 in the central region R1 to supply power signals to the plurality of through electrodes 26 that are arranged along the first direction (e.g., the Y direction). The ground redistribution line 23-2 may be electrically connected to the wirings 223 in the central region R1 to supply ground signals to the plurality of through electrodes 26 that are arranged along the first direction (e.g., the Y direction).

The redistribution lines may be spaced apart from each other along a second direction (e.g., the X direction) perpendicular to the first direction (e.g., the Y direction). In an embodiment, the power redistribution lines 23-1 and the ground redistribution lines 23-2 may be alternately arranged along the second direction (e.g., the X direction). However, embodiments of the present disclosure are not necessarily limited thereto. For example, in some embodiments one or more ground redistribution lines 23-2 may be arranged between two power redistribution lines 23-1, or one or more power redistribution lines 23-1 may be arranged between two ground redistribution lines 23-2b.

In an embodiment, the redistribution pads 23 may be arranged in the central region R1 and may be electrically connected to the through electrodes 26 through the wirings 223 of the wiring layer 221 in the central region R1. The redistribution pads may not be provided in the peripheral region R2.

It will be understood that the number, size, and arrangement of the insulating layers, the wirings, and the redistribution pads of the wiring layer are provided as examples, and embodiments of the present inventive concept are not necessarily limited thereto.

The through electrode 26 (e.g., through silicon via TSV) may extend from the first surface 212 of the substrate 21 to a predetermined depth. The through electrode 26 may directly contact the lowermost wiring of the metal wiring structure. Accordingly, the through electrode 26 may be electrically connected to the redistribution pad 23 by the wirings 223.

In an embodiment, a liner layer may be provided on an outer surface of the through electrode 26. In an embodiment, the liner layer may include silicon oxide or carbon-doped silicon oxide. The liner layer may electrically insulate the through electrode 26 from the substrate 21 and the wiring layer 221.

As illustrated in FIGS. 8 to 10, a first passivation layer 222 including a plurality of first bonding pads 24 and a plurality of first dummy bonding pads 25 provided in an outer surface thereof may be formed.

In an embodiment, the plurality of first bonding pads 24 may be respectively formed on (e.g., formed directly thereon) the redistribution pads 23 in the central region R1 on the wiring layer 221 and the plurality of first dummy bonding pads 25 may be respectively formed in the peripheral region R2 on the wiring layer 221. The first passivation layer 222 may then be formed on the wiring layer 221 and may be arranged to expose the first bonding pads 24 and the first dummy bonding pads 25.

For example, in an embodiment a first protective layer film may be formed on the wiring layer 221 to cover the redistribution pads 23 and a second protective layer may be formed on the first protective layer. The first protective layer may have profiles curved by the redistribution pads 22, and the second protective layer may be formed to completely cover recesses defined by the curved profiles. For example, the second protective layer may be formed to fill gaps between protruding surfaces of the first protective layer by the redistribution pads 23. In an embodiment, the second protective layer may then be planarized so that the second protective layer has a flat upper surface. For example, in an embodiment the first protective layer may include a tetraethyl orthosilicate (TEOS) oxide layer, and the second protective layer may include a high density plasma (HDP) oxide layer.

In an embodiment, a photoresist layer may then be formed on the second protective layer, an exposure process may be performed to form a photoresist pattern having openings that expose portions of the second protective layer, the second protective layer and the first protective layer in the central region R1 may be partially removed using the photoresist pattern as an etching mask to form first openings and the second protective layer in the peripheral region R2 may be partially removed to form second openings. The first openings in the central region R1 may expose the redistribution pads 22 and the second openings in the peripheral region R2 may be formed so as not to penetrate the second protective layer.

In an embodiment, the first bonding pads 24 may then be formed on (e.g., formed directly thereon) the redistribution pads 22 exposed by the first openings of the second and first protective layers in the central region R1, and the first dummy bonding pads 25 may be formed in the second openings of the second protective layer in the peripheral region R2.

Accordingly, the first bonding pads 24 may be formed in the first passivation layer 222 in the central region R1, and the first dummy bonding pads 25 may be formed in the first passivation layer 222 in the peripheral region R2.

In an embodiment, the first bonding pads 24 and the first dummy bonding pads 25 may be formed together by a plating process. For example, in an embodiment the first bonding pads 24a and the first dummy bonding pads 25a may include copper (Cu), aluminum (Al), tungsten (W), nickel (Ni), molybdenum (Mo), gold (Au), silver (Ag), chromium (Cr), tin (Sn), titanium (Ti), or an alloy thereof. In this embodiment, the redistribution pad 23a may include aluminum (Al), and the first bonding pad 24a and the first dummy bonding pad 25a may include copper (Cu).

In an embodiment, the first passivation layer 222a may include the first protective layer and the second protective layer stacked on the first protective layer. However, embodiments of the present disclosure are not necessarily limited thereto. For example, the first passivation layer may further include a third protective layer stacked on the second protective layer. In an embodiment, the first passivation layer may include silicon oxide, silicon nitride, or silicon carbonitride.

Thus, a front insulating layer 22 having the first bonding pads 24 and the first dummy bonding pads 25 in the outer surface thereof may be formed on the first surface 212 of the substrate 21. The front insulating layer 22 may include the wiring layer 221 and the first passivation layer 222. The front insulating layer 22 may include the plurality of redistribution pads 23 as the uppermost wirings in the central region R1, the plurality of first bonding pads 24 respectively disposed on the redistribution pads 23, and the plurality of first dummy bonding pads 25 in the peripheral region R2.

In an embodiment, the through electrode 26, the first bonding pad 24 and the first dummy bonding pad 25 may include a same metal as each other. For example, in an embodiment the metal may include copper (Cu). However, embodiments of the present disclosure are not necessarily limited thereto, and the through electrode, the first bonding pad and the first dummy bonding pad may include a material (e.g., gold (Au)) that can be bonded by inter-diffusion of metals by a high-temperature annealing process.

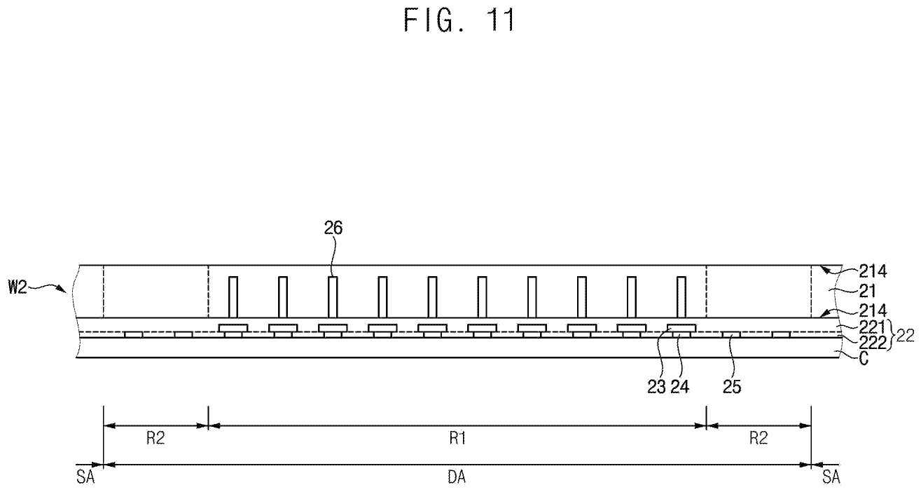

As illustrated in FIGS. 11 to 13, the second surface 214 of the substrate 21 may be partially removed to expose one end portion of the through electrode 26.

In an embodiment, the second surface 214 of the substrate 21 may be partially removed using a substrate support system (WSS). In an embodiment, the second wafer W2 may first be attached to a carrier substrate Cl using an adhesive film, and then, the second surface 214 of the substrate 21 may be partially removed until the end portion of the through electrode 26 is exposed.

In an embodiment, a grinding process such as a back lap process may be performed to partially remove the second surface 214 of the substrate 21, and then, an etching process such as a silicon recess process may be performed to expose the end portion of the through electrode 26. Accordingly, a thickness of the substrate 21 may be reduced to a desired thickness. For example, in an embodiment the substrate 21 may have the thickness in a range of about 20 μm to about 50 μm.

In the back lap process, the entire backside surface of the second wafer W2 may be grinded. In the silicon recess process, only the silicon in the backside surface of the second wafer W2 may be selectively etched. In an embodiment, the etching process may be an isotropic dry etching process. The etching process may include a plasma etching process, etc. The plasma etching process may be performed using inductively coupled plasma, capacitively coupled plasma, microwave plasma, etc.

Since the grinding process and the etching process are performed in the wafer level, the entire second surface 214 of the substrate 21 may be reduced to a uniform thickness. Accordingly, the end portions of the through electrodes 26 may protrude uniformly (e.g., in the vertical direction) from the second surface 214 of the substrate 21 over the entire second surface 214 of the substrate 21 to have same heights.

As illustrated in FIGS. 14 and 15, a second passivation layer 27 as a backside insulating layer having second bonding pads 28 and second dummy bonding pads 29 in an outer surface thereof may be formed on the second surface 214 of the substrate 21.

For example, an etch stop layer may be formed on the second surface 214 of the substrate 21, and a sacrificial layer may be formed on the etch stop layer. The etch stop layer may be conformally formed to cover the end portions of the through electrodes 26 that protrude from the second surface 214 of the substrate 21. The etch stop layer may cover the entire second surface 214 of the substrate 21. For example, in an embodiment the etch stop layer may have a thickness within a range of about 0.1 μm to about 1 μm. The etch stop layer may include a material that can be used to detect a polishing end point in a subsequent chemical mechanical polishing process. For example, in an embodiment the etch stop layer may include a silicon nitride layer. The thickness and material of the etch stop layer may be selected in consideration of a polishing selectivity and polishing conditions in the subsequent chemical mechanical polishing process.

The sacrificial layer may be formed on the etch stop layer to fill a gap between the protruding end portions of the through electrodes 26. In an embodiment, the sacrificial layer may include silicon oxide such as TEOS.

In an embodiment, a chemical mechanical polishing (CMP) process using the etch stop layer to detect a polishing end point may then be performed to remove the sacrificial layer to expose the end portions of the through electrodes 26. Through the CMP process, the end portions of the through electrodes 26 and portions of the etch stop layer covering them may be removed to form an etch stop layer pattern 262 on the second surface 214 of the substrate 21. Accordingly, upper surfaces of the through electrodes 26 may be exposed by the etch stop layer pattern 262. An upper surface of the etch stop layer pattern 262 and the exposed upper surfaces of the through electrodes 26 may be positioned on the same plane (e.g., in the vertical direction).

In an embodiment, the second passivation layer 27 having the second bonding pad 28 disposed therein in the central region R1 to be electrically connected to the through electrode 26 and the second dummy bonding pad 29 that is disposed in the second passivation layer 27 in the peripheral region R2 may be formed on the etch stop layer pattern 262 on the second surface 214 of the substrate 21.

For example, in an embodiment after the second passivation layer is formed on the etch stop layer pattern 262 on the second surface 214 of the substrate 21, a third opening may be formed in the second passivation layer in the central region R1 to expose the through electrode 26 and a fourth opening may be formed in the second passivation layer in the peripheral region R2, and a plating process may be performed to form the second bonding pad 28 in the third opening and the second dummy bonding pad 29 in the third opening. The second bonding pad 28 may be electrically connected to the through electrode 26, and the second dummy bonding pad 29 may not be electrically connected to the through electrode. The second bonding pad 28 may be disposed on the exposed surface of the through electrode 26. In an embodiment, the second passivation layer 27 may include silicon oxide, carbon-doped silicon oxide, silicon carbonitride (SiCN), etc. Accordingly, the first and second bonding pads 26 and 28 may be electrically connected to each other by the through electrode 26.

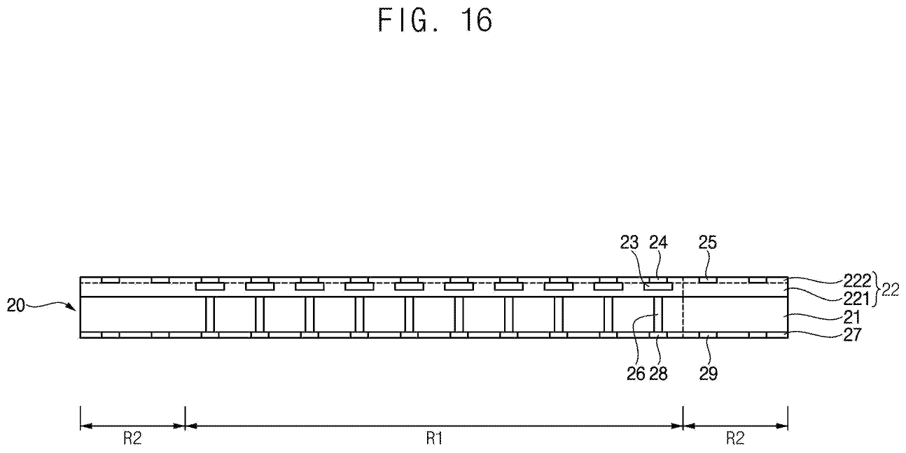

As illustrated in FIG. 16, the second wafer W2 may be cut along the scribe lane region SA to form individual second semiconductor chips (e.g., core dies) 20.

Referring to FIGS. 17 to 21, a plurality of intermediate core dies 20a, 20b, 20c and a top core die 20d may be attached on a first wafer W1.

As illustrated in FIGS. 17 and 18, a plurality of intermediate core dies 20a may be attached in a first stage on the first wafer W1 (e.g., a die-to-wafer hybrid bonding process).

In example embodiments, the intermediate core dies 20a may be disposed on the first wafer W1 to correspond to the die regions DA. The intermediate core die 20a may be stacked such that a first surface 212a of a substrate 21a faces the first wafer W1.

In an embodiment, a die bonding apparatus may pick up an intermediate core die 20a individualized through a sawing process and may bond it to the first wafer W1. In an embodiment, the die bonding apparatus may attach the intermediate core die 20a on the first wafer W1 by performing a thermal compression process at a predetermined temperature (for example, about 400° C. or less). By the thermal compression process, the intermediate core die 20a and the first wafer W1 may be bonded to each other through hybrid bonding. For example, a front surface of the intermediate core die 20a, such as a front insulating layer 23a on the first surface 212a of the substrate 21a may be directly bonded to a backside insulating layer 17 on a substrate 11 of the first wafer W1.

The front surface of the intermediate core die 20a and a backside surface of the first wafer W1 may be bonded to face each other. When the first wafer W1 and the intermediate core die 20a are bonded to each other by die-to-wafer bonding, a second bonding pad 18 of the first wafer W1 and a first bonding pads 24a of the intermediate core die 20a may be bonded to each other by copper-copper hybrid bonding (e.g., Cu—Cu Hybrid Bonding). Second bonding pads 18 of the first wafer W1 and the first bonding pads 24a of the intermediate core die 20a may directly contact each other. Second dummy bonding pads 19 of the first wafer W1 and first dummy bonding pads 25a of the intermediate core die 20a may directly contact each other.

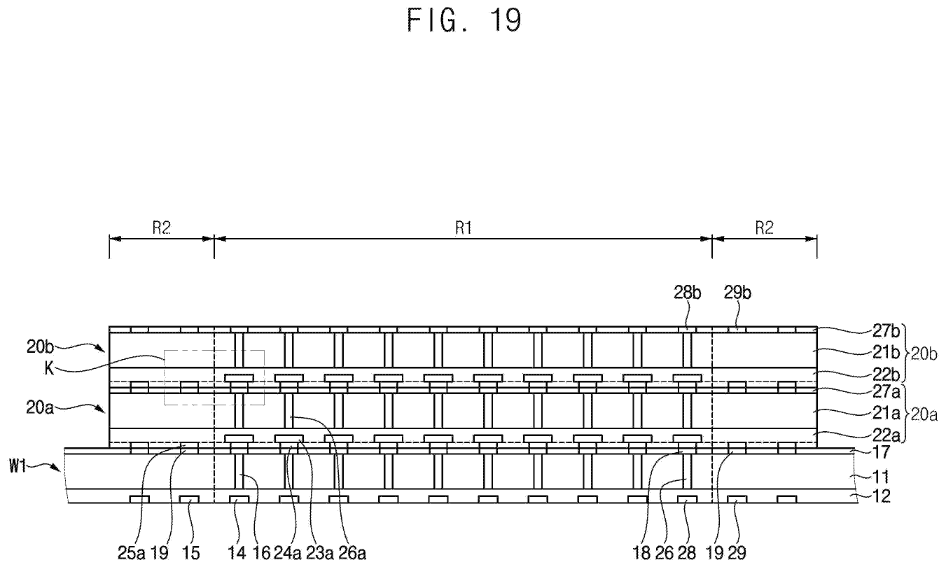

As illustrated in FIGS. 19 and 20, processes the same as or similar to the processes described with reference to FIGS. 17 and 18 may be performed to attach a plurality of intermediate core dies 20b in a second stage on the plurality of first-stage intermediate core dies 20a on the first wafer W1 (e.g., a die-to-wafer hybrid bonding process).

A front surface of the second-stage intermediate core die 20b may be stacked to face the backside surface of the first-stage intermediate core die 20a. By a thermal compression process, the second-stage intermediate core die 20b and the first-stage intermediate core die 20a may be bonded to each other through hybrid bonding. For example, when the first-stage intermediate core die 20a and the second-stage intermediate core die 20b are bonded to each other by die-to-die bonding, a second bonding pad 28a of the first-stage intermediate core die 20a and a first bonding pad 24b of the second-stage intermediate core die 20b may be bonded to each other by copper-copper hybrid bonding. A front insulating layer 22b on the front surface of the second-stage intermediate core die 20b may be directly bonded to a backside insulating layer 27a on a backside surface of the first-stage intermediate core die 20a.

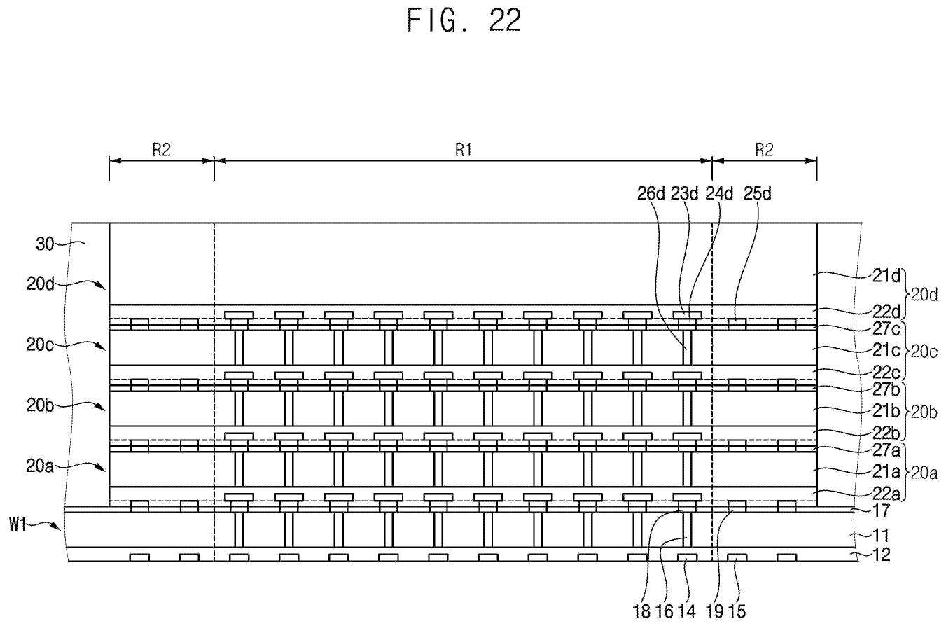

As illustrated in FIG. 22, processes the same as or similar to the processes described with reference to FIGS. 19 and 20 may be performed to attach a plurality of intermediate core dies 20c in a third stage on the second-stage intermediate core dies 20b on the first wafer W1 (e.g., a die-to-wafer hybrid bonding process). In an embodiment, a plurality of top core dies 20d may then be attached on the third-stage intermediate core dies 20c (e.g., a die-to-wafer hybrid bonding process).

A front surface of the third-stage intermediate core die 20c may be stacked to face a backside surface of the second-stage intermediate core die 20b. By a thermal compression process, the third-stage intermediate core die 20c and the second-stage intermediate core die 20b may be bonded to each other through hybrid bonding. For example, a front insulating layer 22c on the front surface of the third-stage intermediate core die 20c may be directly bonded to a backside insulating layer 27b on a backside surface of the second-stage intermediate core die 20b. When the second-stage intermediate core die 20b and the third-stage intermediate core die 20c are bonded to each other by die-to-die bonding, a second bonding pad 28b and a second dummy bonding pad 29b of the second-stage intermediate core die 20b and a first bonding pad 24c and a first dummy bonding pad 25c of the third-stage intermediate core die 20c may be bonded to each other by copper-copper hybrid bonding.

Similarly, a front surface of the top core die 20d may be stacked to face a backside surface of the third-stage intermediate core die 20c. By a thermal compression process, the top core die 20d and the third-stage intermediate core die 20c may be bonded to each other through hybrid bonding. For example, in an embodiment, a front insulating layer 22d on the front surface of the top core die 20d may be directly bonded to a backside insulating layer 27c on a backside surface of the third-stage intermediate core die 20c. When the third-stage intermediate core die 20c and the top core die 20d are bonded to each other by die-to-die bonding, a second bonding pad 28c and a second dummy bonding pad 29c of the third-stage intermediate core die 20c and a first bonding pad 24d and a first dummy bonding pad 25d of the top core die 20d may be bonded to each other by copper-copper hybrid bonding.

Referring to FIG. 22, in an embodiment a gap filling portion 30 may be formed on the first wafer W1 to fill gaps between the intermediate core dies 20a, 20b, 20c stacked in three stages and the top core dies 20d.

In an embodiment, a filling layer may be formed on (e.g., formed directly thereon) the first wafer W1 to cover the intermediate core dies 20a, 20b, 20c stacked in three stages and the top core dies 20d, and an upper portion of the filling layer may be removed to form the gap filling portion that exposes upper surfaces of the top core dies 20d. For example, in an embodiment the gap filling portion may be formed by a conformal deposition process such as an atomic layer deposition (ALD) process or a chemical vapor deposition (CVD) process. The gap filling portion may include an inorganic dielectric layer or an organic dielectric layer. In an embodiment, the inorganic dielectric layer may include silicon oxide, silicon oxynitride, phosphosilicate glass (PSG), boro-phosphosilicate glass (BPSG), etc. The organic dielectric layer may include a polymer or the like. The upper portion of the filling layer may be removed by a chemical mechanical polishing process or a mechanical grinding process.

In an embodiment, conductive bumps 40 as conductive connection members may then be formed on first bonding pads 14 and the first dummy bonding pads 15 of the first wafer W1.

For example, in an embodiment a seed layer may be formed on (e.g., formed directly thereon) the first bonding pad 14 and the first dummy bonding pad 15 of the front insulating layer 12 of the first wafer W1, and a photoresist pattern having openings that expose portions of the seed layer may be formed on the seed layer on the front insulating layer 12. In an embodiment, the openings of the photoresist pattern may then be filled up with a conductive material, the photoresist pattern may be removed and a reflow process may be performed to form solder bumps. For example, the conductive material may be formed on the seed layer by a plating process. Alternatively, the conductive bump may include a pillar bump and a solder bump formed on (e.g., formed directly thereon) the pillar bump.

In an embodiment, the first wafer W1 and portions of the gap filling portions 30 may then be cut along a scribe lane region SA to complete a semiconductor package 100 of FIG. 1.

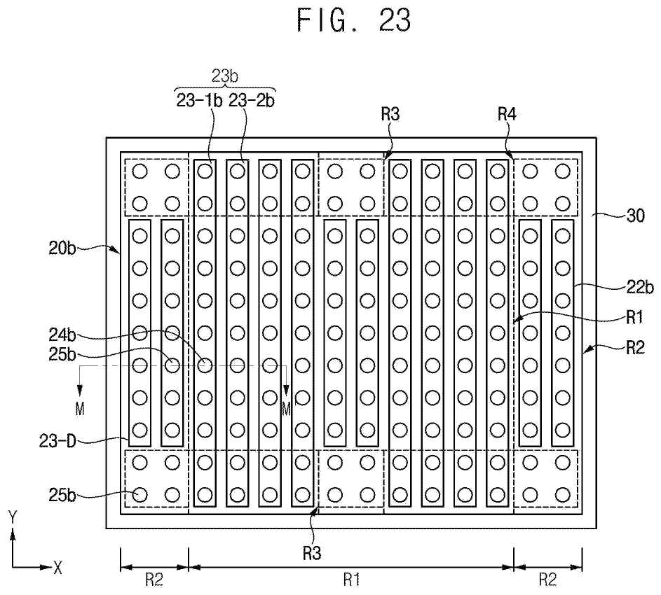

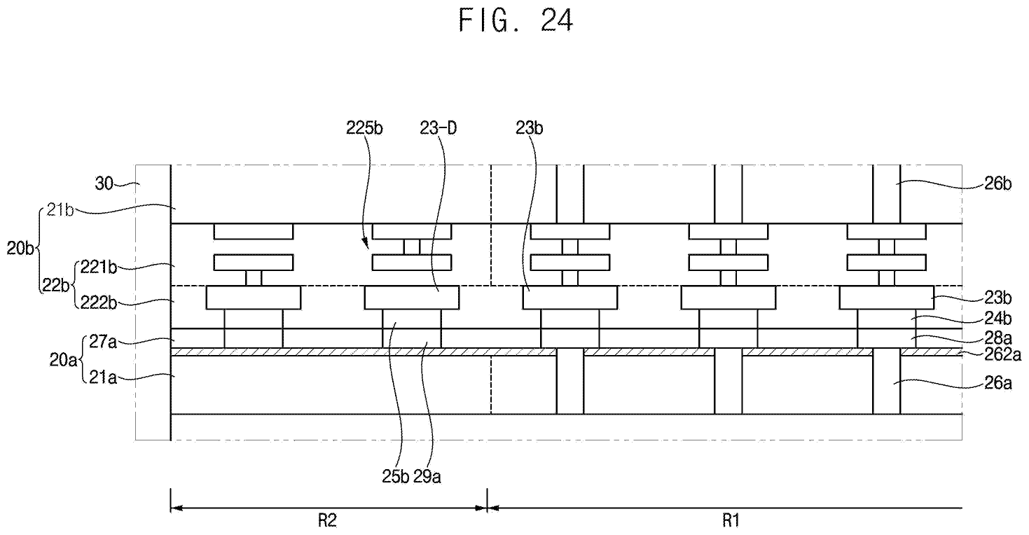

FIG. 23 is a cross-sectional view illustrating a front surface of a second-stage intermediate core die of a semiconductor package in accordance with example embodiments. FIG. 24 is a cross-sectional view taken along the line M-M′ in FIG. 23. The semiconductor package may be substantially the same as or similar to the semiconductor package described with reference to FIG. 1 except for arrangements of wirings including redistribution pads of a wiring layer. Thus, same reference numerals will be used to refer to the same or like elements and any further repetitive explanation concerning the above elements may be omitted for economy of description.

Referring to FIGS. 23 and 24, each of core dies of a semiconductor package may include a front insulating layer disposed on a first side of a substrate. A wiring layer of the front insulating layer may include redistribution pads that are disposed in a central region R1. Additionally, the redistribution pads may be arranged in some portions of a peripheral region R2 of the wiring layer, and the redistribution pads may not be disposed in other portions of the peripheral region R2 of the wiring layer.

As illustrated in FIG. 23, redistribution pads 23b of the second-stage intermediate core die 20b may be arranged to extend from the central region R1 to a portion of the peripheral region R2. Redistribution pads 23b may not be disposed only in central edge regions R3 and corner regions R4 among the peripheral region R2.

As illustrated in FIG. 24, a wiring layer 221b in the peripheral region R2 may include redistribution pads 23-D as uppermost wirings. The redistribution pads 23-D may be arranged in the remaining portions of the peripheral region R2 excluding the central edge regions R3 and the corner regions R4. First dummy bonding pads 25b may be respectively disposed on the redistribution pads 23-D in the peripheral region R2. In an embodiment, the redistribution pads 23-D in the peripheral region R2 may be dummy redistribution pads that are not electrically connected to wirings 225b. For example, at least one of vias or metal wirings among the wirings 225b in the peripheral region R2 may not be formed when vias or metal wires among the wirings 223a in the central region R1 are formed in the same layer. Accordingly, the redistribution pads 23-D in the peripheral region R2 may be electrically insulated.

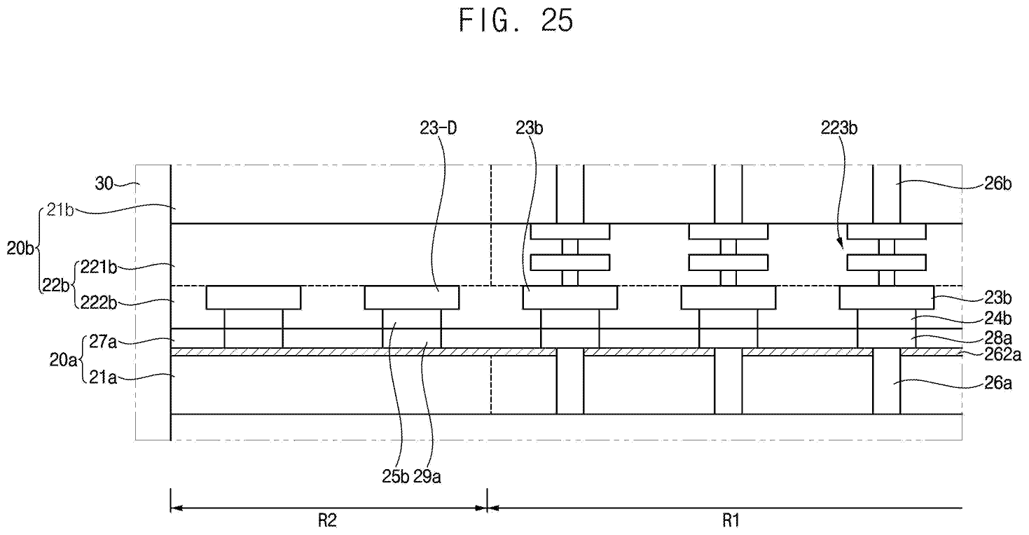

FIG. 25 is a cross-sectional view illustrating a first-stage intermediate core die and a second-stage intermediate core bonded to each other of a semiconductor package in accordance with example embodiments. FIG. 25 is a cross-sectional view taken along the line M-M′ in FIG. 23. The semiconductor package may be substantially the same as or similar to the semiconductor package described with reference to FIG. 1 except for arrangements of wirings including redistribution pads of a wiring layer. Thus, same reference numerals will be used to refer to the same or like elements and any further repetitive explanation concerning the above elements may be omitted for economy of description.

Referring to FIG. 25, a wiring layer 221b in a peripheral region R2 may include only redistribution pads 23-D as uppermost wiring lines. The redistribution pads 23-D may be arranged in the remaining portions of the peripheral region R2 excluding central edge regions R3 and corner regions R4. First dummy bonding pads 25b may be respectively disposed on the redistribution pads 23-D in the peripheral region R2. The redistribution pads 23-D may be dummy redistribution pads that are electrically insulated. For example, wirings other than the redistribution pads in the peripheral region R2 may not be formed when wirings in a central region R1 are formed in the same layer.

In an embodiment, the semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present disclosure. Accordingly, all such modifications are intended to be included within the scope of embodiments of the present disclosure.

What is claimed is:

1. A semiconductor package, comprising:
a first semiconductor chip including:
a first substrate including a first main region and a first peripheral region surrounding the first main region;
a plurality of first bonding pads disposed on a first surface of the first substrate in the first main region;
a plurality of first dummy bonding pads disposed on the first surface of the first substrate in the first peripheral region; and
a first passivation layer disposed on the first surface of the first substrate, the plurality of first bonding pads and the plurality of first dummy bonding pads are disposed in the first passivation layer, wherein the first passivation layer exposes a surface of each of the plurality of first bonding pads and the plurality of first dummy bonding pads; and
a second semiconductor chip stacked on the first semiconductor chip, the second semiconductor chip including:
a second substrate including a second main region and a second peripheral region surrounding the second main region;
a wiring layer on a third surface of the second substrate, an uppermost wiring of the wiring layer in the second main region comprises a plurality of redistribution pads;
a plurality of second bonding pads disposed on the plurality of redistribution pads;
a plurality of second dummy bonding pads disposed on the wiring layer in the second peripheral region; and
a second passivation layer disposed on the wiring layer, the plurality of second bonding pads and the plurality of second dummy bonding pads are disposed in the second passivation layer, wherein the second passivation layer exposes a surface of each of the plurality of second bonding pads and the plurality of second dummy bonding pads,
wherein the plurality of first bonding pads and the plurality of second bonding pads are directly bonded to each other, and
wherein the plurality of first dummy bonding pads and the plurality of second dummy bonding pads are directly bonded to each other.

2. The semiconductor package of claim 1, wherein the first passivation layer and the second passivation layer are directly bonded to each other.

3. The semiconductor package of claim 1, wherein:
the first passivation layer exposes lower surfaces of the plurality of first bonding pads and the plurality of first dummy pads, wherein the exposed lower surfaces of the plurality of first bonding pads and the plurality of first dummy bonding pads are positioned on a same plane as each other,
the second passivation layer exposes upper surfaces of the plurality of second bonding pads and the plurality of second dummy bonding pads, wherein the exposed upper surfaces of the plurality of second bonding pads and the plurality of second dummy bonding pads are positioned on a same plane as each other.

4. The semiconductor package of claim 1, wherein each of the plurality of redistribution pads includes a redistribution line extending in a first direction, and the redistribution lines are spaced apart from each other along a second direction different from the first direction.

5. The semiconductor package of claim 4, wherein the redistribution lines include power redistribution lines and ground redistribution lines alternately arranged along the second direction.

6. The semiconductor package of claim 1, wherein each of the plurality of second bonding pads is in direct contact with the plurality of redistribution pads, respectively.

7. The semiconductor package of claim 1, wherein:
the wiring layer of the second semiconductor chip further includes a plurality of dummy redistribution pads in the second peripheral region; and
the plurality of second dummy bonding pads are disposed on the plurality of dummy redistribution pads, respectively.

8. The semiconductor package of claim 7, wherein wirings of the wiring layer in the second peripheral region are electrically insulated from the plurality of dummy redistribution pads.

9. The semiconductor package of claim 1, wherein the second semiconductor chip further includes a plurality of through electrodes penetrating the second substrate in the second main region.

10. The semiconductor package of claim 9, wherein the plurality of through electrodes are electrically connected to the plurality of second bonding pads.

11. A semiconductor package, comprising:
a buffer die;
a plurality of intermediate core dies sequentially stacked on the buffer die; and
a top core die stacked on an uppermost intermediate core die of the plurality of intermediate core dies,
wherein each of the plurality of intermediate core dies includes:
a substrate including a central region and a peripheral region surrounding the central region, the substrate having a first surface and a second surface opposite the first surface;
a wiring layer disposed on the first surface of the substrate, an uppermost wiring of the wiring layer in the central region comprises a plurality of redistribution pads;
a plurality of first bonding pads respectively disposed on the plurality of redistribution pads;
a plurality of first dummy bonding pads disposed on the wiring layer in the peripheral region;
a first passivation layer on the wiring layer, the plurality of first bonding pads and the plurality of first dummy bonding pads are disposed in the first passivation layer, wherein the first passivation layer exposes a surface of each of the plurality of first bonding pads and the plurality of first dummy bonding pads;
a plurality of second bonding pads disposed on the second surface of the substrate in the central region;
a plurality of second dummy bonding pads disposed on the second surface of the substrate in the peripheral region; and
a second passivation layer on the second surface of the substrate, the plurality of second bonding pads and the plurality of second dummy bonding pads are disposed in the second passivation layer, wherein the second passivation layer exposes a surface of each of the plurality of second bonding pads and the plurality of second dummy bonding pads.

12. The semiconductor package of claim 11, wherein:
the plurality of intermediate core dies include a first intermediate core die and a second intermediate core die stacked on the first intermediate core die;
first bonding pads of the second intermediate core die and second bonding pads of the first intermediate core die are directly bonded to each other; and
first dummy bonding pads of the second intermediate core die and second dummy bonding pads of the first intermediate core die are directly bonded to each other.

13. The semiconductor package of claim 12, wherein the first passivation layer of the second intermediate core die and the second passivation layer of the first intermediate core die are directly bonded to each other.

14. The semiconductor package of claim 11, wherein:
the first passivation layer exposes lower surfaces of the plurality of first bonding pads and the plurality of first dummy bonding pads, wherein the exposed lower surfaces of the plurality of first bonding pads and the plurality of first dummy bonding pads are positioned on a same plane as each other; and
the second passivation layer exposes upper surfaces of the plurality of second bonding pads and the plurality of second dummy bonding pads, wherein the exposed upper surfaces of the plurality of second bonding pads and the plurality of second dummy bonding pads are positioned on a same plane as each other.

15. The semiconductor package of claim 11, wherein:
each of the intermediate core dies further includes a plurality of through electrodes penetrating the substrate in the central region and electrically connecting the plurality of first bonding pads and the plurality of second bonding pads.

16. The semiconductor package of claim 11, wherein each of the plurality of redistribution pads includes a redistribution line extending in a first direction, the redistribution lines are spaced apart from each other along a second direction different from the first direction.

17. The semiconductor package of claim 16, wherein the redistribution lines include power redistribution lines and ground redistribution lines alternately arranged along the second direction.

18. The semiconductor package of claim 11, wherein the plurality of first bonding pads directly contact the plurality of redistribution pads, respectively.

19. The semiconductor package of claim 18, wherein:
the wiring layer further includes a plurality of dummy redistribution pads in the peripheral region; and
the plurality of second dummy bonding pads are disposed on the plurality of dummy redistribution pads, respectively.

20. A semiconductor package, comprising:
a buffer die;
a plurality of intermediate core dies sequentially stacked on the buffer die;
a top core die stacked on an uppermost intermediate core die of the plurality of intermediate core dies; and
a sealing member on the buffer die and covering outer surfaces of the plurality of intermediate core dies and the top core die,
wherein each of the plurality of intermediate core dies includes:
a substrate including a central region and a peripheral region surrounding the central region, the substrate having a first surface and a second surface opposite the first surface;
a wiring layer disposed on the first surface of the substrate, an uppermost wiring of the wiring layer in the central region comprises a plurality of redistribution pads;
a plurality of first bonding pads respectively disposed on the plurality of redistribution pads;
a plurality of first dummy bonding pads disposed on the wiring layer in the peripheral region;
a first passivation layer on the wiring layer, the first bonding pads and the first dummy bonding pads are disposed in the first passivation layer, wherein the first passivation layer exposes a surface of each of the first bonding pads and the first dummy bonding pads;
a plurality of second bonding pads disposed on the second surface of the substrate in the central region;
a plurality of second dummy bonding pads disposed on the second surface of the substrate in the peripheral region; and
a second passivation layer on the second surface of the substrate film, the second bonding pads and the second dummy bonding pads are disposed in the second passivation layer, wherein the second passivation layer exposes a surface of each of the second bonding pads and the second dummy bonding pads, and
wherein the first bonding pads directly contact the plurality of redistribution pads respectively.
